(19) United States
(12) Patent Application Publication
(10) Pub. No.: US 2021/0043744 A1
(43) Pub. Date: Feb. 11, 2021

(54) SEMICONDUCTOR DEVICE, METHOD OF MANUFACTURING SEMICONDUCTOR DEVICE, AND ELECTRONIC APPARATUS

(71) Applicant: SONY SEMICONDUCTOR SOLUTIONS CORPORATION, KANAGAWA (JP)

(72) Inventor: KATSUHIKO TAKEUCHI, KANAGAWA (JP)

(21) Appl. No.: 16/978,043

(22) PCT Filed: Feb. 14, 2019
(86) PCT No.: PCT/JP2019/005228

§ 371 Date: Sep. 3, 2020

(30) Foreign Application Priority Data
Mar. 12, 2018 (JP) 2018-044046

(51) Int. Cl. H01L 29/423; H01L 29/778; H01L 29/66

(52) U.S. Cl. CPC H01L 29/42356; H01L 29/66462; H01L 29/778

(57) ABSTRACT

A semiconductor device including: a semiconductor layer; an inter-layer insulating film having a through hole and a low-dielectric constant region; a gate electrode including an embedded section and a widened section; and a gate insulating film provided between the embedded section of the gate electrode and the semiconductor layer. The through hole is provided to be opposed to the semiconductor layer. The low-dielectric constant region is provided to at least a portion of an area around the through hole. The embedded section is embedded in the through hole of the inter-layer insulating film. The widened section is opposed to the semiconductor layer with the inter-layer insulating film interposed between the widened section and the semiconductor layer and is widened to an area around the embedded section.

### TECHNICAL FIELD

The present technology relates to a semiconductor device including a semiconductor layer and a gate electrode, a method of manufacturing the semiconductor device, and an electronic apparatus including this semiconductor device.

### BACKGROUND ART

A semiconductor device such as a field effect transistor (FET: Field Effect Transistor) includes, for example, a semiconductor layer including a channel layer and a gate electrode opposed to this semiconductor layer. As the shape of the gate electrode, a so-called T-shaped gate electrode is proposed (see, for example, PTL 1). This T-shaped gate electrode includes an embedded section that is embedded in the insulating film and a widened section that is provided to be wider than the embedded section to cover the embedded section.

### CITATION LIST

### Patent Literature

PTL 1: Japanese Unexamined Patent Application Publication No. H9-27505

### SUMMARY OF THE INVENTION

Such a semiconductor device is required to improve, for example, a transistor characteristic such as an off characteristic.

It is thus desirable to provide a semiconductor device that allows the transistor characteristic to be improved, a method of manufacturing the semiconductor device, and an electronic apparatus including this semiconductor device.

A semiconductor device according to an embodiment of the present technology includes: a semiconductor layer; an inter-layer insulating film having a through hole and a low-dielectric constant region; a gate electrode including an embedded section and a widened section; and a gate insulating film provided between the embedded section of the gate electrode and the semiconductor layer. The through hole is provided to be opposed to the semiconductor layer. The low-dielectric constant region is provided to at least a portion of an area around the through hole. The embedded section is embedded in the through hole of the inter-layer insulating film. The widened section is opposed to the semiconductor layer with the inter-layer insulating film interposed between the widened section and the semiconductor layer and is widened to an area around the embedded section.

An electronic apparatus according to an embodiment of the present technology includes the above-described semiconductor device according to the embodiment of the present technology.

The semiconductor device and electronic apparatus according to the respective embodiments of the present technology are each provided with the gate insulating film between the embedded section of the gate electrode and the semiconductor layer. This suppresses the occurrence of a leak current, decrease in a withstand voltage, and the like caused by contact between the gate electrode and the semiconductor layer.

A method of manufacturing a semiconductor device according to an embodiment of the present technology includes: forming a semiconductor layer; forming an inter-layer insulating film that covers the semiconductor layer; forming a through hole and a low-dielectric constant region in the inter-layer insulating film; forming a gate insulating film on at least a bottom of the through hole; and forming a gate electrode by embedding an electrically conductive film in the through hole of the inter-layer insulating film via the gate insulating film and covering the through hole with the electrically conductive film widened to an area around the through hole. The through hole is disposed to be opposed to the semiconductor layer. The low-dielectric constant region is provided to at least a portion of an area around the through hole.

In the method of manufacturing the semiconductor device according to the embodiment of the present technology, the gate insulating film is formed on the bottom of the through hole of the inter-layer insulating film. This gate insulating film is thus disposed between the gate electrode and the semiconductor layer. This gate insulating film suppresses the occurrence of a leak current, decrease in a withstand voltage, and the like caused by contact between the gate electrode and the semiconductor layer.

In the semiconductor device, method of manufacturing the semiconductor device, and electronic apparatus including this semiconductor device according to the respective embodiments of the present technology, the gate insulating film is provided between the gate electrode (embedded section) and the semiconductor layer. For example, this makes it possible to suppress decrease in the off characteristic such as the occurrence of a leak current and decrease in a withstand voltage. This makes it possible to improve a transistor characteristic.

It is to be noted that the above-described contents are an example of the present disclosure. The effects of the present disclosure are not limited to those described above, but may be other different effects or may further include any other effects.

### BRIEF DESCRIPTION OF DRAWING

FIG. 1 is a cross-sectional schematic diagram illustrating a configuration of a main portion of a semiconductor device according to an embodiment of the present technology.

FIG. 2 is a schematic diagram illustrating a top configuration of the semiconductor device illustrated in FIG. 1.

FIG. 3 is an energy band configuration diagram of the semiconductor device (Vg=0 V) illustrated in FIG. 1.

FIG. 4A is a cross-sectional schematic diagram illustrating a step of manufacturing the semiconductor device illustrated in FIG. 1.

FIG. 4B is a cross-sectional schematic diagram illustrating a step subsequent to FIG. 4A.

FIG. 4C is a cross-sectional schematic diagram illustrating a step subsequent to FIG. 4B.

FIG. 4D is a cross-sectional schematic diagram illustrating a step subsequent to FIG. 4C.

FIG. 4E is a cross-sectional schematic diagram illustrating a step subsequent to FIG. 4D.

FIG. 5 is an energy band configuration diagram of the semiconductor device (at time of an off operation) illustrated in FIG. 1.

FIG. 6 is a schematic cross-sectional view of a carrier depletion region formed at the time of the off operation of the semiconductor device illustrated in FIG. 1.

FIG. 7 is a cross-sectional schematic diagram illustrating a configuration of a main portion of a semiconductor device according to a comparative example 1.

FIG. 8 is a cross-sectional schematic diagram illustrating a configuration of a main portion of a semiconductor device according to a comparative example 2.

FIG. 9 is a cross-sectional schematic diagram illustrating a configuration of a main portion of a semiconductor device according to a comparative example 3.

FIG. 10A is a diagram illustrating gate-drain capacity (Cgd) at time of an on operation of the semiconductor device illustrated in FIG. 1.

FIG. 10B is a diagram illustrating the gate-drain capacity (Cgd) at the time of the off operation of the semiconductor device illustrated in FIG. 1.

FIG. 11 is a cross-sectional schematic diagram for describing widths Wa and W23 illustrated in FIGS. 10A and 10B.

FIG. 12 is a cross-sectional schematic diagram illustrating a configuration of a main portion of a semiconductor device according to a modification example 1.

FIG. 13 is a schematic diagram illustrating a top configuration of the semiconductor device illustrated in FIG. 12.

FIG. 14 is a cross-sectional schematic diagram illustrating a configuration of a main portion of a semiconductor device according to a modification example 2.

FIG. 15 is a schematic diagram illustrating a top configuration of the semiconductor device illustrated in FIG. 14.

FIG. 16A is a cross-sectional schematic diagram illustrating a step of manufacturing the semiconductor device illustrated in FIG. 14.

FIG. 16B is a cross-sectional schematic diagram illustrating a step subsequent to FIG. 16A.

FIG. 16C is a cross-sectional schematic diagram illustrating a step subsequent to FIG. 16B.

FIG. 17 is a block diagram illustrating an example of a configuration of a wireless communication apparatus to which the semiconductor device illustrated in FIG. 1 or the like is applied.

### MODES FOR CARRYING OUT THE INVENTION

The following describes an embodiment of the present technology in detail with reference to the drawings. It is to be noted that description is given in the following order.

### 1. Embodiment

A semiconductor device provided with a gate insulating film between a T-shaped gate electrode and a semiconductor layer

### 2. Modification Example 1

An example in which a low-dielectric constant region on a drain side is greater in size than a low-dielectric constant region on a source side

### 3. Modification Example 2

An example in which low-dielectric constant regions are provided to a plurality of insulating layers (first insulating layer and second insulating layer) included in an inter-layer insulating film

### Embodiment

### (Configuration of Semiconductor Device 1)

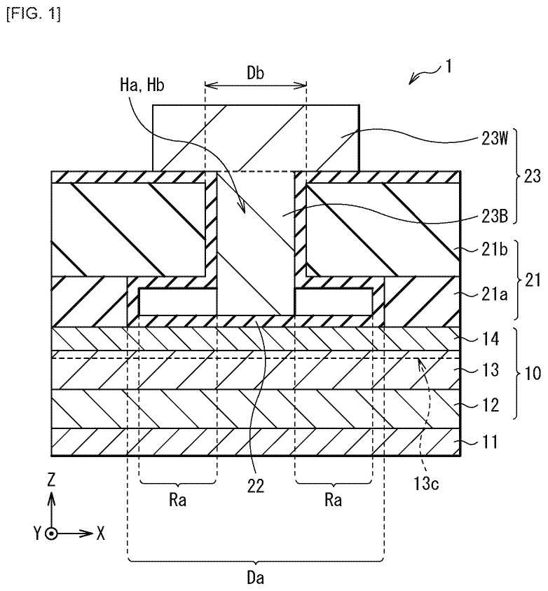

FIG. 1 is a cross-sectional view of the configuration of a main portion of a semiconductor device (semiconductor device 1) according to an embodiment to which the present technology is applied. FIG. 2 is a top view of the semiconductor device 1. The following describes the detailed configuration of the semiconductor device 1 on the basis of these diagrams.

The semiconductor device 1 includes a semiconductor layer 10, a gate insulating film 22, an inter-layer insulating film 21, and a gate electrode 23 on a substrate 11 in this order. The semiconductor layer 10 includes a channel layer 13. The gate electrode 23 has a so-called T-shaped structure. The gate electrode 23 includes an embedded section 23B that is embedded in the inter-layer insulating film 21 and a widened section 23W that is provided above the inter-layer insulating film 21. The semiconductor device 1 includes paired source and drain electrodes (source electrode 24s and drain electrode 24d) (FIG. 2) electrically coupled to the semiconductor layer 10. The source electrode 24s, the gate electrode 23, and the drain electrode 24d are disposed in this order along the channel length direction (X direction in FIG. 2).

The substrate 11 includes a semiconductor material. The substrate 11 like this includes, for example, a III-V compound semiconductor material. For example, a semi-insulating monocrystal GaN (gallium nitride) substrate is used for the substrate 11. It is also possible to use, for the substrate 11, a substrate material having a lattice constant different from the lattice constant of the channel layer 13. Examples of such a material included in the substrate 11 include SiC (silicon carbide), sapphire, Si (silicon), or the like. At this time, a buffer layer (buffer layer 12 described below) between the substrate 11 and the channel layer 13 adjusts the lattice constant. There are provided island-shaped active regions a above the substrate 11 (FIG. 2). The adjacent active regions a are separated, for example, by the ion implantation of B (boron) or the like. This subjects the plurality of active regions a to element separation. Each active region a is provided with the gate electrode 23, the source electrode 24s, the drain electrode 24d, and the like. Element separation may be performed in a method other than ion implantation. For example, the channel layer 13 may be divided by dry etching for element separation.

The semiconductor layer 10 has a structure in which the buffer layer 12, the channel layer 13, and a barrier layer 14 are, for example, stacked in order from the substrate 11 side.

The buffer layer 12 includes, for example, a compound semiconductor layer that has been epitaxially grown on the substrate 11. A compound semiconductor that is favorably lattice-matched with the substrate 11 is used to configure the buffer layer 12. For example, there is provided a u-GaN (u- indicates that no impurity is added; the same applies hereinafter) epitaxial growth layer with no impurity added on the substrate 11 including a monocrystal GaN substrate. When the substrate 11 and the channel layer 13 have different lattice constants, the buffer layer 12 provided between the substrate 11 and the channel layer 13 allows the channel layer 13 to have a favorable crystalline state and allows wafer warpage to be suppressed. For example, when the substrate 11 includes Si and the channel layer 13 includes GaN, it is possible to use, for example, AlN (aluminum nitride), AlGaN (aluminum gallium nitride), GaN, or the like for the buffer layer 12. The buffer layer 12 may be configured as a single layer or may have a stacked structure. When the buffer layer 12 includes the materials of three elements, the respective materials may be gradually different in composition in the buffer layer 12.

The channel layer 13 between the buffer layer 12 and the barrier layer 14 is the current path between the source electrode 24s and the drain electrode 24d. This channel layer 13 has carriers accumulated therein owing to the polarization between the channel layer 13 and the barrier layer 14. There is provided a two dimensional electron gas (2DEG: Two Dimensional Electron gas) layer 13c near the junction surface (heterojunction interface) with the barrier layer 14. That is, the semiconductor device 1 is a GaN-based hetero field effect transistor (HFET). It is preferable that the channel layer 13 like this include a compound semiconductor material in which carriers are likely to be accumulated owing to the polarization between the compound semiconductor material and the barrier layer 14. For example, the channel layer 13 includes GaN epitaxially grown on the buffer layer 12. The channel layer 13 may include u-GaN with no impurity added. In the channel layer 13 including u-GaN, the impurity scattering of carriers in the channel layer 13 is suppressed, allowing the carrier mobility to be increased.

GaN is a wide-gap semiconductor material and has a high dielectric breakdown voltage. In addition, the semiconductor layer 10 including GaN is operable at high temperature and also has high saturated drift velocity. The two dimensional electron gas layer 13c formed in the channel layer 13 including GaN has high mobility and high sheet electron density. The semiconductor device 1 that is such a GaN-based hetero field effect transistor is able to perform low-resistance, high-speed, and high-withstand-voltage operations. The semiconductor device 1 is favorably used for a power device, an RF (Radio Frequency) device, and the like.

There may be provided a lower barrier layer (not illustrated) between the channel layer 13 and the buffer layer 12. The provided lower barrier layer makes it possible to suppress electron distribution widening on the buffer layer 12 side in the channel layer 13. This makes it possible to suppress a short channel effect or the like and improve the transistor characteristic.

The barrier layer 14 provided between the channel layer 13 and the inter-layer insulating film 21 is favorably lattice-matched with the channel layer 13. This barrier layer 14 forms a heterojunction interface with the channel layer 13. The barrier layer 14 includes, for example, a compound semiconductor material having a wider band gap than the band gap of the channel layer 13. For example, Al_{(1-x-y)}GaₓIn_{y}N (0≤x<1 and 0≤y<1) epitaxially grown on the channel layer 13 is used for the barrier layer 14. The barrier layer 14 may include u-Al_{(1-x-y)}GaₓIn_{y}N with no impurity added. The use of the barrier layer 14 including u-Al_{(1-x-y)}GaₓIn_{y}N suppresses the impurity scattering of carriers in the channel layer 13, allowing the carrier mobility to be increased. The barrier layer 14 may be configured as a single layer or may have a stacked structure. For example, the barrier layer 14 may include a stacked structure of Al_{(1-x-y)}GaₓIn_{y}N different from each other in composition. Alternatively, Al_{(1-x-y)}GaₓIn_{y}N may be gradually different in composition in the barrier layer 14.

The inter-layer insulating film 21 provided on the barrier layer 14 includes a stacked film in which a first insulating layer 21a and a second insulating layer 21b are stacked from the barrier layer 14 side. This inter-layer insulating film 21 including the first insulating layer 21a and the second insulating layer 21b is provided with through holes Ha and Hb and low-dielectric constant regions Ra. The embedded section 23B of the gate electrode 23 passes through the through holes Ha and Hb. The low-dielectric constant regions Ra are disposed between the widened section 23W of the gate electrode 23 and the semiconductor layer 10. The through holes Ha and Hb are provided at positions opposed to the semiconductor layer 10. The low-dielectric constant regions Ra provided to the inter-layer insulating film 21 each decrease gate-drain capacity (Cgd) and gate-source capacity (Cgs) in this way. This allows for gain improvement.

The first insulating layer 21a on the barrier layer 14 is provided with the through hole Ha (first through hole) having a width (size in the X direction in FIGS. 1 and 2) Da. Here, this through hole Ha is provided with the low-dielectric constant regions Ra. Each of these low-dielectric constant regions Ra is a region having a lower dielectric constant than the dielectric constant of a material included in the inter-layer insulating film 21 (first insulating layer 21a). The low-dielectric constant region Ra includes a space of the first insulating layer 21a. The embedded section 23B is provided to a portion (region corresponding to the through hole Hb) of the region of the through hole Ha of the first insulating layer 21a. The low-dielectric constant region Ra is provided around the embedded section 23B (through hole Hb) to surround this embedded section 23B (FIGS. 1 and 2). The low-dielectric constant regions Ra are provided, for example, around the embedded section 23B in substantially the same size. That is, the low-dielectric constant region Ra disposed between the gate electrode 23 and the source electrode 24s has substantially the same size as the size of the low-dielectric constant region Ra disposed between the gate electrode 23 and the drain electrode 24d. It is preferable to provide the low-dielectric constant regions Ra to surround the area around the embedded section 23B. It is, however, sufficient if the low-dielectric constant regions Ra are provided to at least portions (e.g., between the gate electrode 23 and the source electrode 24s and between the gate electrode 23 and the drain electrode 24d) of the area around the embedded section 23B. The low-dielectric constant regions Ra may each include an insulating material having a lower dielectric constant than the dielectric constant of a material included in the inter-layer insulating film 21 (first insulating layer 21a).

This first insulating layer 21a includes, for example, Al₂O₃ (aluminum oxide) having a thickness (size in the Z direction in FIG. 1) of about 50 nm. The first insulating layer 21a like this functions as an insulating film for the barrier layer 14 and has a function of protecting the surface of the barrier layer 14 from contamination caused by an impurity. Examples of this impurity include an ion and the like. In addition, a favorable interface formed between the first insulating layer 21a and the barrier layer 14 suppresses the degradation of the device characteristic. It is preferable that the first insulating layer 21a include a material which allows for wet etching. 1:5 or more is preferable as the selection ratio for wet etching between a material included in the second insulating layer 21b and a material included in the first insulating layer 21a.

The second insulating layer 21b is opposed to the barrier layer 14 with the first insulating layer 21a interposed therebetween. This second insulating layer 21b is provided with the through hole Hb (second through hole) having a smaller width Db than the width Da of the through hole Ha of the first insulating layer 21a. This through hole Hb of the second insulating layer 21b communicates with the through hole Ha of the first insulating layer 21a. The embedded section 23B passes through both the through hole Ha and the through hole Hb. In plan (XY plane in FIG. 1) view, the through hole Hb is disposed in the middle section of the through hole Ha. The through hole Hb of the second insulating layer 21b defines the size of the embedded section 23B. The width Db of the through hole Hb is substantially the same as the width of the embedded section 23B. The through hole Hb of the second insulating layer 21b may have a tapered shape. For example, the lower section (first insulating layer 21a side) of the through hole Hb may have a smaller width than the width of the upper section (widened section 23W side). The width of the through hole Hb is limited, for example, by the specifications of an apparatus for a lithography step. In a case where it is necessary to make the gate length smaller than that of the specifications of the apparatus, the through hole Hb having such a tapered shape may be, however, formed.

This second insulating layer 21b includes, for example, SiO₂ (silicon oxide) having a thickness of about 100 nm. The second insulating layer 21b like this functions as an insulating film for the barrier layer 14 along with the first insulating layer 21a and has a function of protecting the surface of the barrier layer 14 from contamination caused by an impurity. It is preferable that the second insulating layer 21b include a material which allows for dry etching. 1:5 or more is preferable as the selection ratio for dry etching between a material included in the first insulating layer 21a and a material included in the second insulating layer 21b.

In the present embodiment, the side wall and bottom surface of the through holes Ha and Hb of this inter-layer insulating film 21 are provided with the gate insulating film 22. The gate insulating film 22 provided to the bottom surface of the inter-layer insulating film 21 is disposed between the semiconductor layer 10 (barrier layer 14) and the embedded section 23B of the gate electrode 23. That is, the semiconductor device 1 has an MIS (Metal Insulator Semiconductor) structure. Although the details are described below, this suppresses decrease in the off characteristic or the like caused by contact between the semiconductor layer 10 and the gate electrode 23.

The gate insulating film 22 covers the side wall and bottom surface of the through holes Ha and Hb of the inter-layer insulating film 21 from above the inter-layer insulating film 21 (second insulating layer 21b). The gate insulating film 22 on the inter-layer insulating film 21 is disposed between the widened section 23W of the gate electrode 23 and the inter-layer insulating film 21. The gate insulating film 22 covering the side wall of the through holes Ha and Hb is disposed between the second insulating layer 21b and the embedded section 23B and the first insulating layer 21a and the low-dielectric constant regions Ra (spaces). The gate insulating film 22 covering the bottom surface of the through holes Ha and Hb is disposed not only between the semiconductor layer 10 and the embedded section 23B, but also between the semiconductor layer 10 and the spaces (low-dielectric constant regions Ra) of the first insulating layer 21a.

This gate insulating film 22 includes, for example, Al₂O₃, HfO₂ (hafnium oxide), or the like having a thickness of about 10 nm. The gate insulating film 22 may be configured as a single layer or may have a stacked structure. The gate insulating film 22 like this functions as an insulating film for the barrier layer 14 and the inter-layer insulating film 21 and has a function of protecting the surface of the barrier layer 14 from contamination caused by an impurity. Examples of this impurity include an ion and the like. In addition, a favorable interface formed between the gate insulating film 22 and the barrier layer 14 suppresses the degradation of the device characteristic.

The gate electrode 23 opposed to the semiconductor layer 10 with the gate insulating film 22 interposed therebetween includes the embedded section 23B and the widened section 23W in this order from the gate insulating film 22 side. The gate electrode 23 like this includes, for example, a stacked film in which nickel (Ni) and gold (Au) are sequentially stacked from the substrate 11 (gate insulating film 22) side.

The embedded section 23B that is embedded in the through holes Ha and Hb of the inter-layer insulating film 21 is provided on the gate insulating film 22. That is, the gate insulating film 22 is provided between the barrier layer 14 and the embedded section 23B. The width (size in the X direction in FIG. 1) of this embedded section 23B defines a gate length (Lg) of the gate electrode 23.

The widened section 23W opposed to the semiconductor layer 10 with the inter-layer insulating film 21 interposed therebetween covers the embedded section 23B to be widened to the area around the embedded section 23B. The widened section 23W is widened, for example, over the entire circumference of the embedded section 23B. The widened section 23W may also be widened in a portion of the area around the embedded section 23B. The widened section 23W provided on the embedded section 23B increases the gate electrode 23 in area (cross-sectional area), allowing the gate resistance (Rg) to be decreased. It is possible to decrease the gate resistance of the gate electrode 23 including the embedded section 23B and the widened section 23W, namely the gate electrode 23 having a T-shaped structure, while decreasing the gate length. This allows the cutoff frequency (fmax) to be increased. The semiconductor device 1 including the gate electrode 23 is thus favorably used as a high-frequency device.

The gate electrode 23 has the source electrode 24s disposed on one side. The gate electrode 23 has the drain electrode 24d on the other side. These source electrode 24s and drain electrode 24d are each joined to the barrier layer 14 through ohmic junction. The source electrode 24s and drain electrode 24d like these each include a stacked film in which, for example, titanium (Ti), aluminum (Al), nickel (Ni), and gold (Au) are stacked in this order from the substrate 11 side.

### (Band Structure of Semiconductor Device 1)

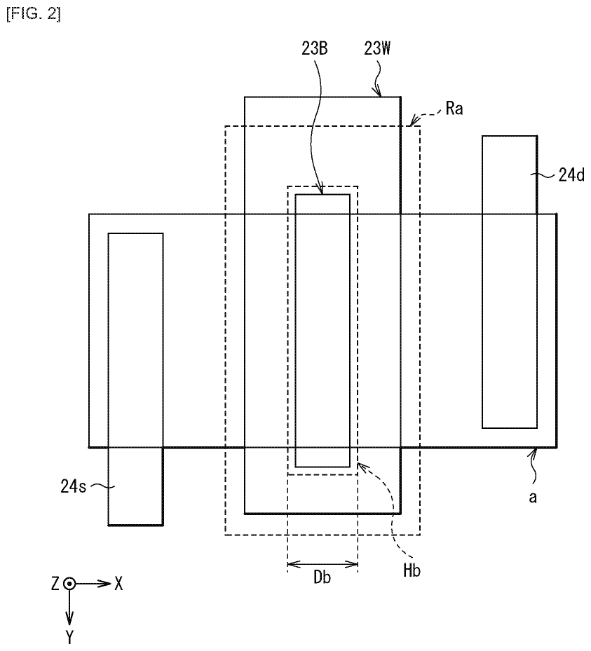

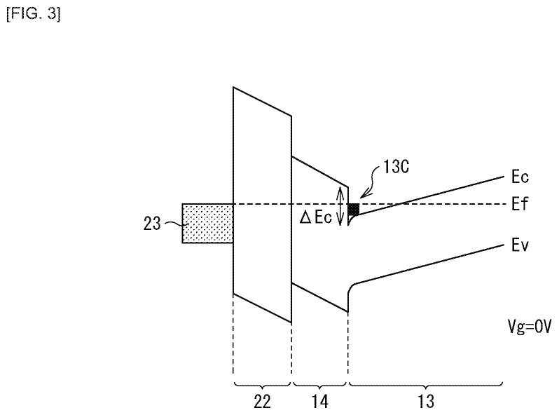

FIG. 3 is an energy band configuration diagram of components below the gate electrode 23 of the semiconductor device 1 having the above-described configuration. FIG. 3 illustrates a junction state with no gate voltage Vg applied. It is to be noted that this energy band configuration diagram illustrates a case where the channel layer 13 includes GaN and the barrier layer 14 includes the mixed crystal of Al_{0.3}Ga_{0.7}N.

In the semiconductor device 1, the barrier layer 14 having a wider band gap than that of the channel layer 13 is joined to the channel layer 13 having a narrow band gap. Spontaneous polarization or piezo polarization or both of them therefore cause carriers to be accumulated near the junction surface in the channel layer 13 between the channel layer 13 and the barrier layer 14. This forms the two dimensional electron gas layer 13c in the channel layer 13.

In addition, a discontinuous amount ΔEc is sufficiently large (0.3 eV here) between the conduction band edge of the channel layer 13 and the conductor edge of the barrier layer 14. Accordingly, a negligibly small number of carriers (electrons) are distributed in the barrier layer 14 as compared with the number of carriers (electrons) distributed in the channel layer 13.

### (Method of Manufacturing Semiconductor Device 1)

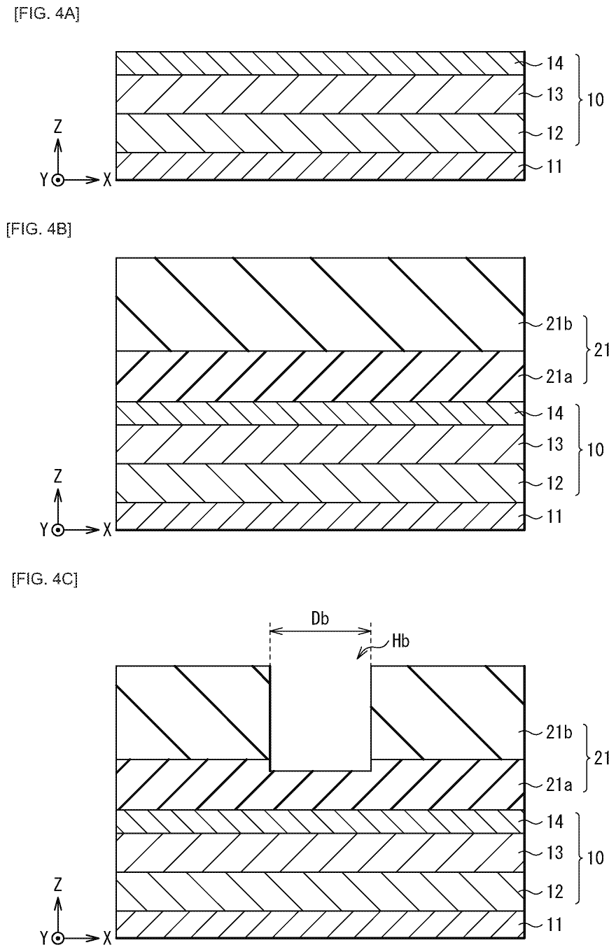

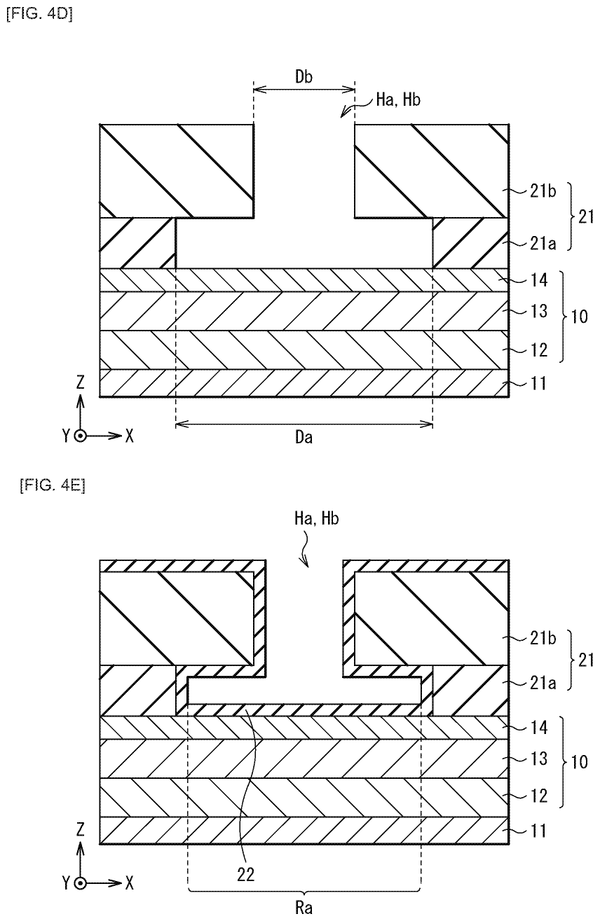

The semiconductor device 1 having such a configuration is manufacturable, for example, as follows. FIGS. 4A to 4E are cross-sectional schematic diagrams illustrating a method of manufacturing the semiconductor device 1 in the order of steps.

As illustrated in FIG. 4A, the buffer layer 12, the channel layer 13, and the barrier layer 14 are first formed by epitaxial growth in this order on the substrate 11 including, for example, Si. After the barrier layer 14 is formed, for example, the source electrode 24s and the drain electrode 24d are formed (see FIG. 2). The source electrode 24s and the drain electrode 24d are formed, for example, in a predetermined region on the barrier layer 14 by performing annealing treatment or the like after an electrically conductive film is formed that is joined to the barrier layer 14 through ohmic junction. To decrease the contact resistance of the source electrode 24s and drain electrode 24d, selective regrowth, ion implantation, or the like may be performed. After the source electrode 24s and the drain electrode 24d are formed, for example, element separation is performed. The element separation is performed, for example, by performing the ion implantation of B (boron) or the like on the region between adjacent elements. The ion implantation increases the resistance of the region between elements and element separation is performed (the active region a is formed). The source electrode 24s and the drain electrode 24d may be formed and element separation may be performed in subsequent (e.g., after the gate electrode 23 is formed) steps.

After the barrier layer 14 is formed, the first insulating layer 21a and the second insulating layer 21b are formed on the entire barrier layer 14 in this order as illustrated in FIG. 4B. This forms the inter-layer insulating film 21. The first insulating layer 21a is formed, for example, by forming a film of Al₂O₃ (aluminum oxide) by using atomic layer deposition (ALD: Atomic Layer Deposition). The second insulating layer 21b is formed, for example, by forming a film of SiO₂ (silicon oxide) by using chemical vapor deposition (CVD: Chemical Vapor Deposition).

After the second insulating layer 21b is formed, the through hole Hb having the width Db is formed in a predetermined region of the second insulating layer 21b as illustrated in FIG. 4C. The through hole Hb is formed at a position opposed to the semiconductor layer 10. The first insulating layer 21a is exposed on the bottom surface of the through hole Hb. It is preferable to form the through hole Hb like this by using dry etching. The use of dry etching allows the width Db to be more accurately defined. The use of appropriate materials allows the selection ratio of the second insulating layer 21b to the first insulating layer 21a for dry etching to be increased. This makes it possible to suppress film reduction in the first insulating layer 21a or the like and suppress the degradation of the semiconductor layer 10. The through hole Hb of the second insulating layer 21b may have a tapered shape. The above-described through hole Hb having a tapered shape is formable, for example, by adjusting a dry etching condition.

After the through hole Hb is formed in the second insulating layer 21b, the through hole Ha having the width Da is formed in the first insulating layer 21a as illustrated in FIG. 4D. The through hole Ha is formed in communication with the through hole Hb. The barrier layer 14 is exposed on the bottom surface of the through hole Ha. It is preferable to form the through hole Ha like this by using wet etching. Performing side etching on the first insulating layer 21a in the horizontal direction (X direction in FIG. 4D) via the through hole Hb causes the through hole Ha to be formed that has the greater width Da than the width Db. The use of appropriate materials allows the selection ratio of the first insulating layer 21a to the second insulating layer 21b for wet etching to be increased. This makes it possible to suppress increase in the width Db of the through hole Hb of the second insulating layer 21b. The use of wet etching to form the through hole Ha makes it possible to suppress the degradation of the surface of the semiconductor layer 10.

After the through hole Ha is formed in the first insulating layer 21a, the gate insulating film 22 is formed to cover the side wall and bottom surface of the through holes Ha and Hb from above the second insulating layer 21b as illustrated in FIG. 4E. The gate insulating film 22 is formed, for example, by forming a film of Al₂O₃ (aluminum oxide) by using ALD. The use of ALD allows for uniform film formation. The exposed surfaces of the barrier layer 14, first insulating layer 21a, and second insulating layer 21b are thus covered with a uniform film.

When each of the low-dielectric constant regions Ra of the inter-layer insulating film 21 is a space of the first insulating layer 21a, it is sufficient if the gate insulating film 22 is formed and the following step (step of forming the gate electrode 23) is then performed. In a case where the low-dielectric constant regions Ra of the inter-layer insulating film 21 each include an insulating material having a lower dielectric constant than that of a material included in the inter-layer insulating film 21, it is sufficient if the gate insulating film 22 is formed and this insulating material is then embedded in the through holes Ha and Hb. After the insulating material is embedded, a portion of this insulating material is removed with anisotropy. This forms the low-dielectric constant regions Ra.

After the gate insulating film 22 is formed, the embedded section 23B formed in the through holes Ha and Hb of the inter-layer insulating film 21 and the widened section 23W patterned in a predetermined shape is formed on the inter-layer insulating film 21. This forms the gate electrode 23. This gate electrode 23 is formed, for example, by subsequently performing mask evaporation on Ni (nickel) and Au (gold). The semiconductor device 1 illustrated in FIGS. 1 and 2 is completed through such steps.

### (Operation of Semiconductor Device 1)

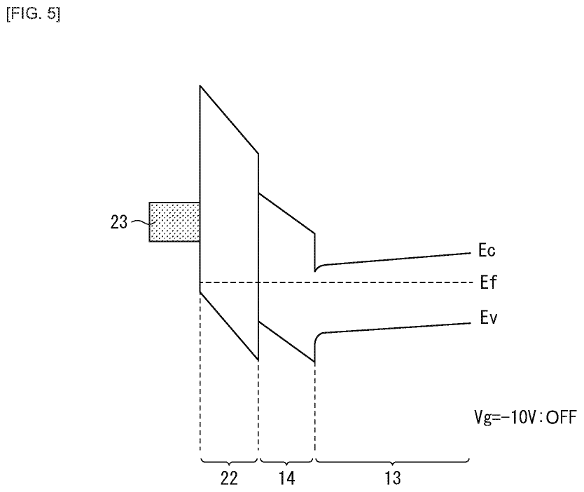

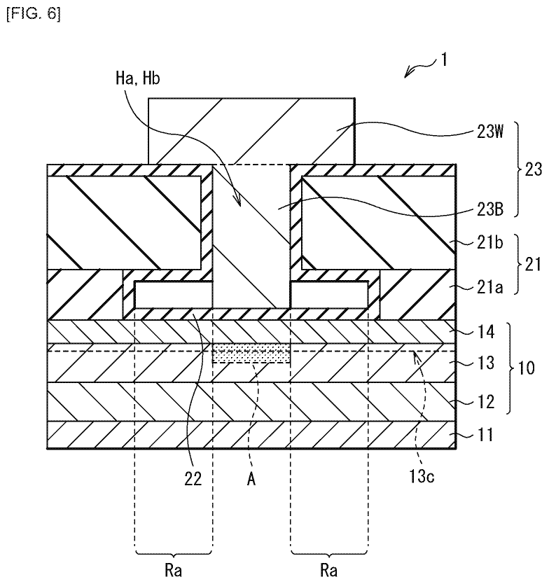

The operation of the semiconductor device 1 like this is described by using the energy band configuration diagram of FIG. 5 and the cross-sectional view of the semiconductor device 1 of FIG. 6 along with FIG. 3 above. Here, the operation in a case where the semiconductor device 1 is a depletion-type transistor having a threshold voltage of about −5 V is described.

FIG. 5 is a diagram at the time of an off operation (Vg=−10 V). In addition, FIG. 5 illustrates a case where the channel layer 13 includes GaN and the barrier layer 14 includes the mixed crystal of Al_{0.3}Ga_{0.7}N as in FIG. 3.

When the negative gate voltage Vg (e.g., about −10 V) is applied to the gate electrode 23 in the semiconductor device 1, the number of carriers decreases in a region (carrier depletion region A) of the channel layer 13 immediately below the gate electrode 23 as illustrated in the cross-sectional view of FIG. 6. This decreases the number of electrons in the channel layer 13 and causes few drain currents Id to flow. The energy band configuration at this time is as illustrated in FIG. 5. Conduction band energy Ec of the channel layer 13 is completely higher than a Fermi level Ef.

Meanwhile, the application of the positive gate voltage Vg (e.g., about 1 V) to the gate electrode 23 results in the state at the time of an on operation. In this case, the carrier depletion region A illustrated in the cross-sectional view of FIG. 6 disappears, the number of electrons in the channel layer 13 increases, and the drain current Id is modulated. The energy band configuration at this time is as illustrated in FIG. 3. The conduction band energy Ec of the channel layer 13 is lower than the Fermi level Ef.

### (Workings and Effects of Semiconductor Device)

The semiconductor device 1 according to the present embodiment is provided with the gate electrode 23 including the embedded section 23B and the widened section 23W, namely the T-shaped gate electrode 23. This makes it possible to decrease the gate resistance while decreasing the gate length. It is thus possible to increase the cutoff frequency (fmax).

In addition, the low-dielectric constant regions Ra are provided to the inter-layer insulating film 21 (first insulating layer 21a) around the embedded section 23B. This decreases the gate-drain capacity (Cgd) and the gate-source capacity (Cgs). This allows for gain improvement.

Further, the gate insulating film 22 is provided between the embedded section 23B of the gate electrode 23 and the semiconductor layer 10. This makes it possible to suppress the occurrence of a leak current, decrease in a withstand voltage, and the like caused by contact between the gate electrode 23 and the semiconductor layer 10. It is thus possible to suppress decrease in the off characteristic. The following describes these workings and effects by using comparative examples (comparative examples 1, 2, and 3).

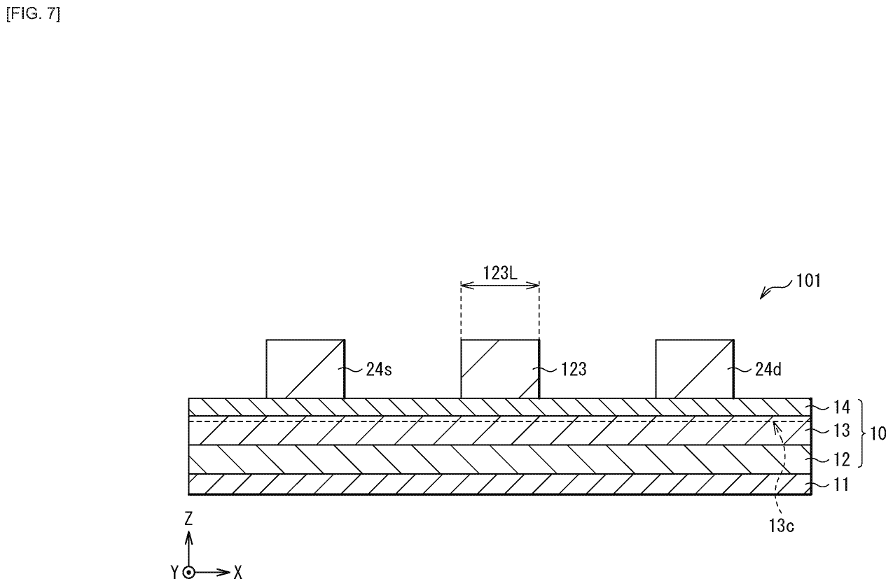

FIG. 7 schematically illustrates the cross-sectional configuration of a main portion of a semiconductor device (semiconductor device 101) according to a comparative example 1. This semiconductor device 101 is HFET. The semiconductor device 101 includes a gate electrode 123, the source electrode 24s, and the drain electrode 24d on the semiconductor layer 10. The efficiency index of such HFET as a high-frequency device is expressed, for example, by using the cutoff frequency (fmax). This cutoff frequency (fmax) increases with decrease in the gate length (gate length 123L) of the gate electrode 123. The decreased gate length 123L, however, decreases the gate electrode 123 in cross-sectional area to increase the gate resistance (Rg). The increased gate resistance (Rg) decreases the cutoff frequency (fmax). That is, decrease in the gate length 123L and reduction in the gate resistance (Rg) have a trade-off relationship. The adjustment of only one of them does not make it possible to increase the cutoff frequency (fmax).

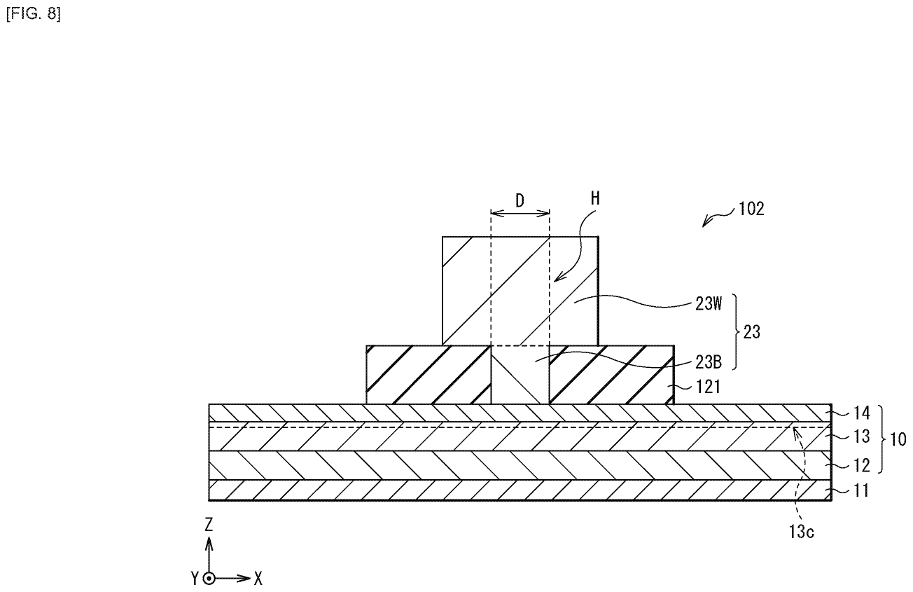

A semiconductor device (semiconductor device 102) according to a comparative example 2 illustrated in FIG. 8 includes the T-shaped gate electrode 23. In this gate electrode 23, the width of the embedded section 23B, namely a width D of a through hole H of an inter-layer insulating film 121, is decreased to decrease the gate length. In addition, the widened section 23W is provided. These decrease the gate resistance (Rg). It is thus possible in the semiconductor device 102 to solve the above-described trade-off problem with the semiconductor device 101, allowing the cutoff frequency (fmax) to be increased.

In the semiconductor device 102, the widened section 23W of the gate electrode 23, however, increases the gate-drain capacity (Cgd) and the gate-source capacity (Cgs). The increased gate-drain capacity (Cgd) decreases the gain. A method is thus conceivable that provides the inter-layer insulating film 121 with a low-dielectric constant region to suppress increase in the gate-drain capacity (Cgd).

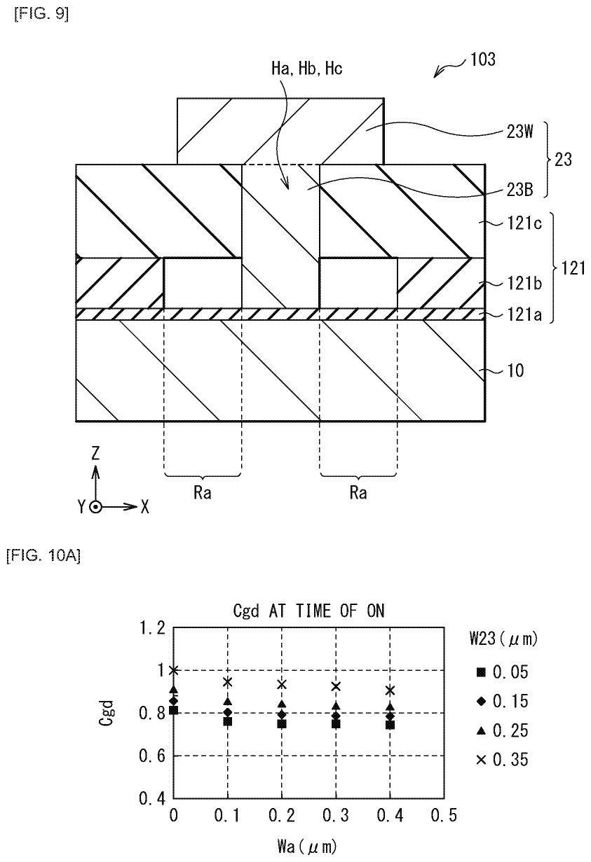

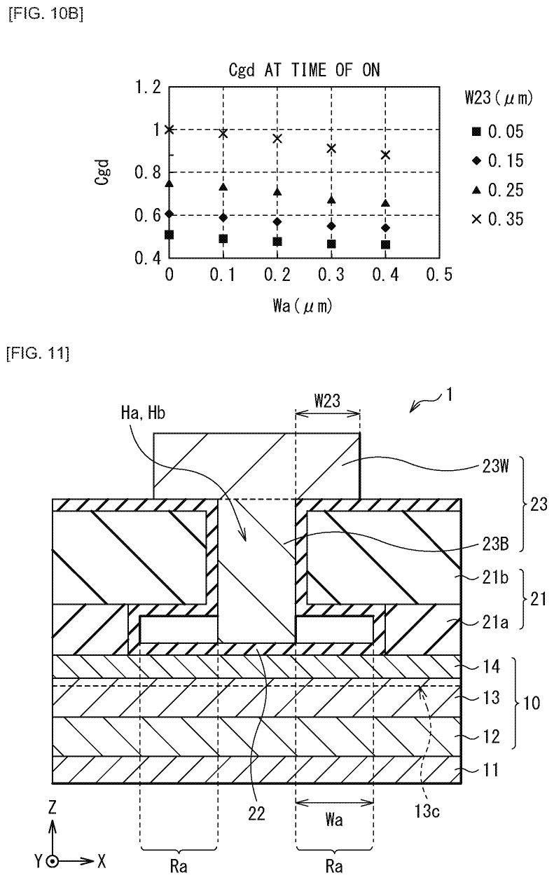

A semiconductor device 103 according to a comparative example 3 illustrated in FIG. 9 is provided with the embedded section 23B of the gate electrode 23 in the through holes Ha, Hb, and Hc of the inter-layer insulating film 121. The low-dielectric constant regions Ra are provided to the inter-layer insulating film 121 around this embedded section 23B. The inter-layer insulating film 121 has a stacked structure in which, for example, a first insulating layer 121a, a second insulating layer 121b, and a third insulating layer 121c are stacked in this order from the semiconductor layer 10 side. The low-dielectric constant regions Ra each include a space of the second insulating layer 121b. Increase in the gate-drain capacity (Cgd) is suppressed in the semiconductor device 103 including the low-dielectric constant region Ra like this.

This semiconductor device 103 is, however, provided with no gate insulating film (e.g., gate insulating film 22 in FIG. 1) between the embedded section 23B and the semiconductor layer 10. That is, the gate electrode 23 and the semiconductor layer 10 are in contact with each other. This facilitates the contact between the gate electrode 23 and the semiconductor layer 10 to decrease the off characteristic or the like. The decrease in the off characteristic is, for example, increase in a leak current, decrease in a withstand voltage, and the like.

In addition, in the semiconductor device 103, the width of the embedded section 23B (size in the X direction of FIG. 9), namely the gate length, is defined by the width of the through hole Ha of the first insulating layer 121a. It is therefore preferable to form the through hole Ha in the first insulating layer 121a by using dry etching. The first insulating layer 121a is provided in contact with the semiconductor layer 10. This may cause the dry etching on the first insulating layer 121a to degrade the surface of the semiconductor layer 10. Specifically, for example, the exposure of the semiconductor layer 10 to plasma at the time of dry etching causes the semiconductor layer 10 to degrade. The ions included in etching gas enters the semiconductor layer 10 to cause the semiconductor layer 10 to degrade. The degradation of the surface of the semiconductor layer 10 like these causes decrease in the on characteristic and decrease in the off characteristic. The decrease in the on characteristic is, for example, increase in sheet resistance or the like.

The semiconductor device 1 addresses such problems with the semiconductor devices 101, 102, and 103 as follows. The semiconductor device 1 is first provided with the gate electrode 23 including the embedded section 23B and the widened section 23W, namely the T-shaped gate electrode 23. This makes it possible to decrease the gate resistance while decreasing the gate length. It is thus possible to increase the cutoff frequency (fmax).

In addition, the low-dielectric constant regions Ra are provided to the inter-layer insulating film 21 (first insulating layer 21a) around the embedded section 23B. This decreases the gate-drain capacity (Cgd) and the gate-source capacity (Cgs).

FIGS. 10A and 10B each illustrate a result obtained by calculating the size of the gate-drain capacity (Cgd) of the semiconductor device 1 through simulation. A width Wa in each of FIGS. 10A and 10B is a value indicating the size of the low-dielectric constant region Ra. A width W₂₃ is a value indicating the size of the widened section 23W. FIG. 11 illustrates the widths Wa and W₂₃. FIG. 10A illustrates a result obtained by causing the semiconductor device 1 to perform an on operation. FIG. 10B illustrates a result obtained by causing the semiconductor device 1 to perform an off operation.

These results prove that it is possible in the semiconductor device 1 to decrease the gate-drain capacity (Cgd) by about 10% both at the time of the on operation and at the time of the off operation as compared with a case where no low-dielectric constant region Ra is provided (width Wa=0 μm). This allows the semiconductor device 1 to decrease the gate-drain capacity (Cgd) for gain improvement.

In addition, the semiconductor device 1 is provided with the gate insulating film 22 between the embedded section 23B of the gate electrode 23 and the semiconductor layer 10. This makes it possible to suppress the occurrence of a leak current, decrease in a withstand voltage, and the like caused by contact between the gate electrode 23 and the semiconductor layer 10. It is thus possible to suppress decrease in the off characteristic. Especially when the barrier layer 14 includes In (indium), the leak current is likely to increase. Accordingly, when the barrier layer 14 includes In, the off characteristic is significantly improved.

Additionally, in the semiconductor device 1, the width of the embedded section 23B is defined by the width Db of the through hole Hb of the second insulating layer 21b. This makes it possible to form, by wet etching, the through hole Ha of the first insulating layer 21a in contact with the semiconductor layer 10. It is thus possible to suppress the degradation of the surface of the semiconductor layer 10 caused by dry etching and suppress decrease in the on characteristic and decrease in the off characteristic.

As described above, in the present embodiment, the gate insulating film 22 is provided between the gate electrode 23 (embedded section 23B) and the semiconductor layer 10. For example, this makes it possible to suppress decrease in the off characteristic such as the occurrence of a leak current and decrease in a withstand voltage. This makes it possible to improve the transistor characteristic.

In addition, the gate insulating film 22 is also provided to the low-dielectric constant regions Ra and covers the surface of the semiconductor layer 10. This makes it possible to improve the interface characteristic and more effectively improve the transistor characteristic.

It is to be noted that the case of the depletion-type semiconductor device 1 has been described in the above-described embodiment, but the same applies to the case of the enhancement-type semiconductor device 1.

The following describes modification examples of the above-described embodiment. In the following description, the same components as those of the above-described embodiment are denoted by the same reference signs and description thereof is omitted as appropriate.

### Modification Example 1

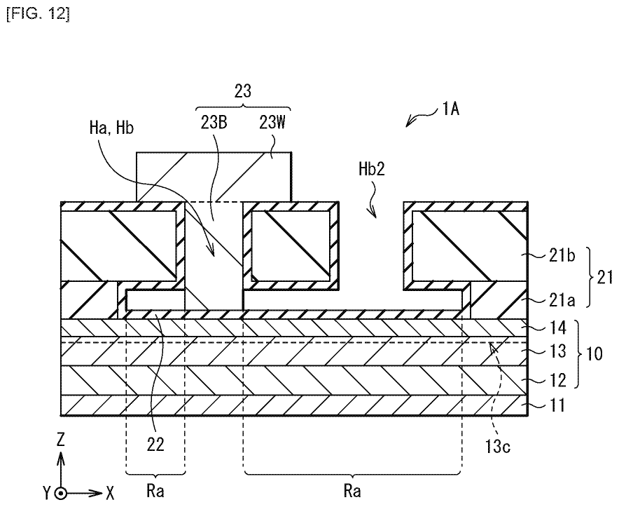

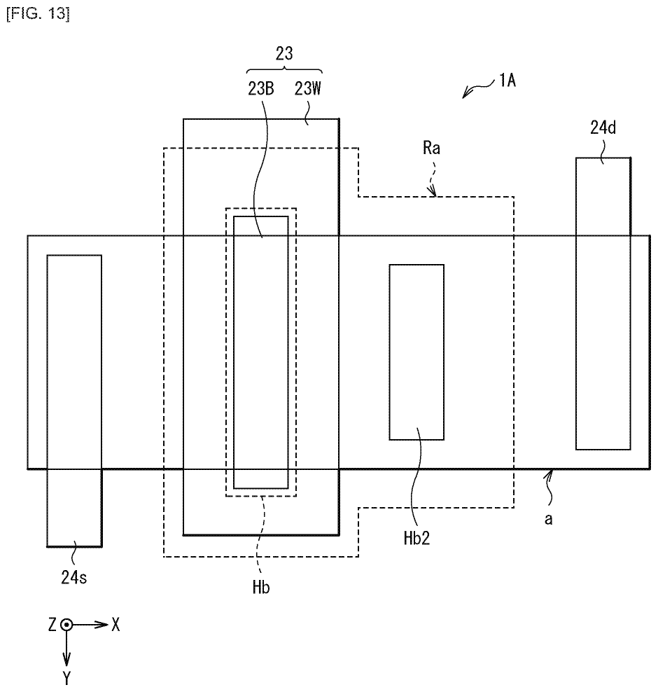

FIG. 12 schematically illustrates the cross-sectional configuration of a main portion of a semiconductor device (semiconductor device 1A) according to a modification example 1 of the above-described embodiment. FIG. 13 illustrates the planar configuration of the semiconductor device 1A. In this semiconductor device 1A, the low-dielectric constant region Ra between the gate electrode 23 and the drain electrode 24d is provided to be wider than the low-dielectric constant region Ra between the gate electrode 23 and the source electrode 24s. Except for this point, the semiconductor device 1A has a configuration similar to that of the semiconductor device 1 and also achieves similar workings and effects.

The second insulating layer 21b of the semiconductor device 1A has a through hole Hb2 disposed between the gate electrode 23 and the drain electrode 24d in addition to the through hole Hb. Performing side etching on the first insulating layer 21a via this through hole Hb2 widens a space of the first insulating layer 21a to one side (drain electrode 24d side). This makes the low-dielectric constant region Ra between the gate electrode 23 and the drain electrode 24d wider than the low-dielectric constant region Ra between the gate electrode 23 and the source electrode 24s. It is possible in this semiconductor device 1A to further decrease the gate-drain capacity (Cgd) without increasing the distance between the gate electrode 23 and the source electrode 24s.

The semiconductor device 1A according to the present modification example is also provided with the gate insulating film 22 between the gate electrode 23 (embedded section 23B) and the semiconductor layer 10 as with the above-described semiconductor device 1. For example, this makes it possible to suppress decrease in the off characteristic such as the occurrence of a leak current and decrease in a withstand voltage. This makes it possible to improve the transistor characteristic.

In addition, the low-dielectric constant region Ra between the gate electrode 23 and the drain electrode 24d is wider than the low-dielectric constant region Ra between the gate electrode 23 and the source electrode 24s. This makes it possible to further decrease the gate-drain capacity (Cgd) without increasing the distance between the gate electrode 23 and the source electrode 24s. That is, it is possible to effectively decrease the gate-drain capacity (Cgd) while suppressing increase in the source resistance. The semiconductor device 1A is favorable in a case where it is requested to keep the low source resistance as the device characteristic.

### Modification Example 2

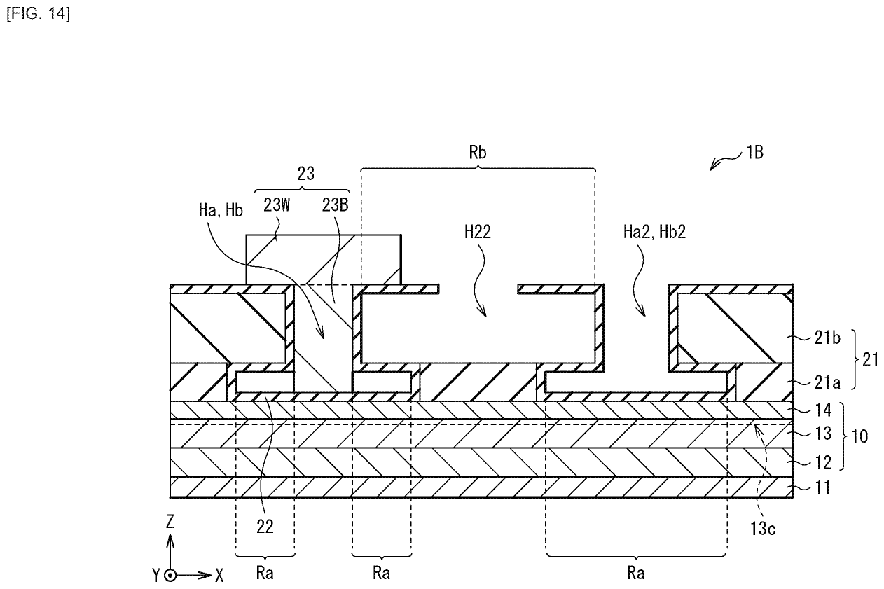

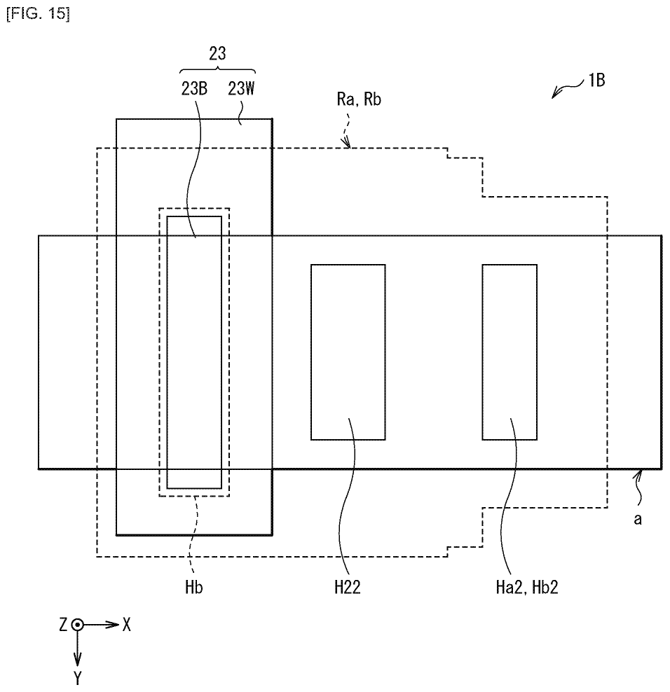

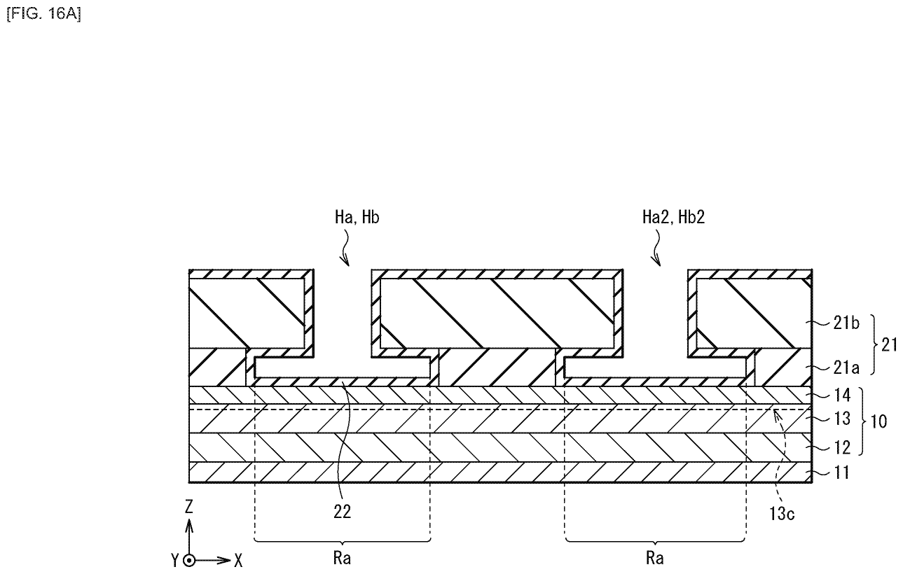

FIG. 14 schematically illustrates the cross-sectional configuration of a main portion of a semiconductor device (semiconductor device 1B) according to a modification example 2 of the above-described embodiment. FIG. 15 illustrates the planar configuration of the semiconductor device 1B. In this semiconductor device 1B, the low-dielectric constant region Ra (low-dielectric constant regions Ra and Rb) between the gate electrode 23 and the drain electrode 24d is provided to be wider than the low-dielectric constant region Ra between the gate electrode 23 and the source electrode 24s as in the semiconductor device 1A. In addition, these low-dielectric constant regions Ra and Rb provided between the gate electrode 23 and the drain electrode 24d includes the low-dielectric constant region Rb provided to the second insulating layer 21b. Except for this point, the semiconductor device 1B has a configuration similar to that of the semiconductor device 1 and also achieves similar workings and effects.

The second insulating layer 21b of the semiconductor device 1B has the through hole Hb2 disposed between the gate electrode 23 and the drain electrode 24d in addition to the through hole Hb. The low-dielectric constant region Rb of the second insulating layer 21b is provided between the through hole Hb and the through hole Hb2. This low-dielectric constant region Rb is a region having a lower dielectric constant than the dielectric constant of a material included in the inter-layer insulating film 21 (second insulating layer 21b). The low-dielectric constant region Rb includes a space of the second insulating layer 21b. The low-dielectric constant region Rb may include an insulating material having a lower dielectric constant than the dielectric constant of a material included in the inter-layer insulating film 21 (second insulating layer 21b). It is preferable that the second insulating layer 21b include a material which allows for wet etching. 1:5 or more is preferable as the selection ratio for wet etching between a material included in the gate insulating film 22 and a material included in the second insulating layer 21b.

The first insulating layer 21a has a through hole Ha2 that communicates with this through hole Hb2. For example, the through hole Ha and through hole Ha2 of the first insulating layer 21a are separated by the insulating material of the first insulating layer 21a. The through hole Ha and the through hole Ha2 may communicate with each other.

The gate insulating film 22 covers the side walls and bottom surfaces of the through holes Ha, Ha2, Hb, and Hb2 from above the inter-layer insulating film 21. The gate insulating film 22 on the second insulating layer 21b has a through hole H22 between the through hole Hb and through hole Hb2 of the second insulating layer 21b. This through hole H22 of the gate insulating film 22 is opposed, for example, to the region between the through hole Ha and through hole Ha2 of the first insulating layer 21a. In plan view, the low-dielectric constant region Rb of the second insulating layer 21b is disposed around this through hole H22. As described below, performing side etching on the second insulating layer 21b via this through hole H22 of the gate insulating film 22 causes the low-dielectric constant region Rb to be formed in the second insulating layer 21b between the gate electrode 23 and the drain electrode 24d. In the present modification example, this low-dielectric constant region Rb makes the low-dielectric constant regions Ra and Rb between the gate electrode 23 and the drain electrode 24d wider than the low-dielectric constant region Ra between the gate electrode 23 and the source electrode 24s. It is thus possible in this semiconductor device 1B to further decrease the gate-drain capacity (Cgd) without increasing the distance between the gate electrode 23 and the source electrode 24s.

FIGS. 14 and 15 each illustrates the example in which the gate insulating film 22 has the one through hole H22 between the through hole Hb and through hole Hb2 of the second insulating layer 21b, but the gate insulating film 22 may also have the plurality of through holes H22. The plurality of provided through holes H22 allows the gate-drain capacity (Cgd) to be further decreased.

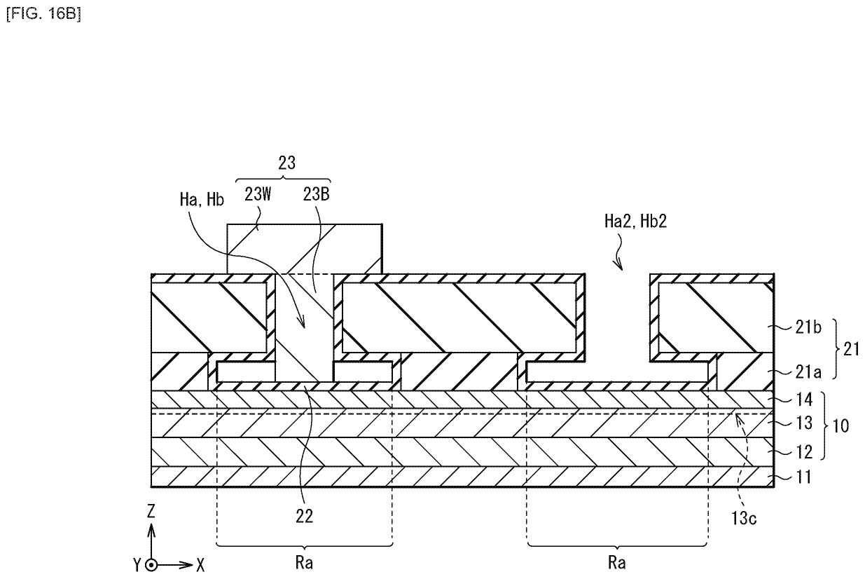

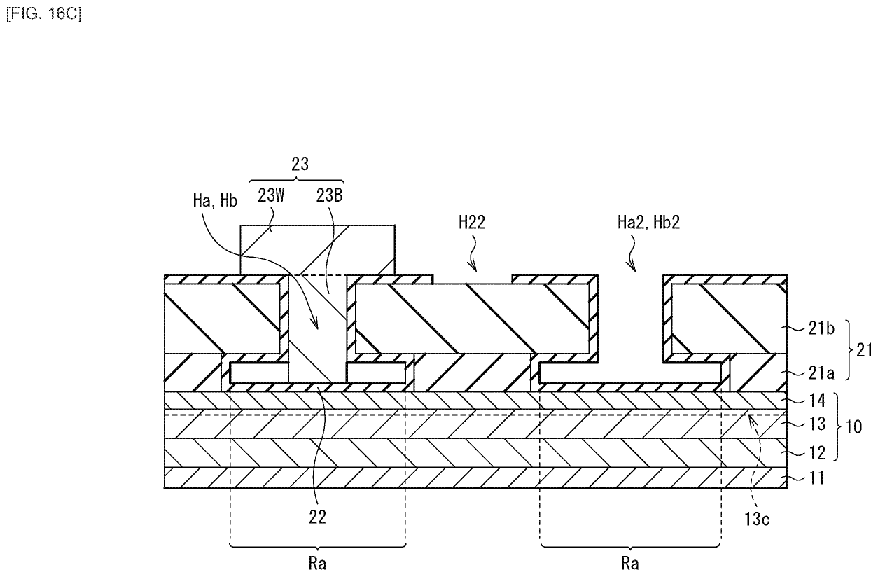

The semiconductor device 1B is manufacturable, for example, as follows. FIGS. 16A to 16C are cross-sectional schematic diagrams illustrating a method of manufacturing the semiconductor device 1B in the order of steps.

First, as described in the above-described embodiment, the semiconductor layer 10 and the inter-layer insulating film 21 are formed on the substrate 11 (FIG. 4B). The through holes Hb and Hb2 are then formed in the second insulating layer 21b, for example, by using dry etching. Next, wet etching is performed on the first insulating layer 21a via these through holes Hb and Hb2. This subjects the first insulating layer 21a to side etching and causes the through hole Ha and the through hole Ha2 to be formed in the first insulating layer 21a. The through hole Ha communicates with the through hole Hb. The through hole Ha2 communicates with the through hole Hb2.

Afterward, as illustrated in FIG. 16A, the gate insulating film 22 is formed on the side walls and bottom surfaces of the through holes Ha, Ha2, Hb, and Hb2 from above the inter-layer insulating film 21. The gate insulating film 22 is formed, for example, by forming a film of Al₂O₃ (aluminum oxide) by using ALD. The use of ALD allows for uniform film formation. The exposed surfaces of the barrier layer 14, first insulating layer 21a, and second insulating layer 21b are thus covered with a uniform film.

When each of the low-dielectric constant regions Ra of the inter-layer insulating film 21 is a space of the first insulating layer 21a, it is sufficient if the gate insulating film 22 is formed and the following step (step of forming the gate electrode 23) is then performed. In a case where the low-dielectric constant regions Ra of the inter-layer insulating film 21 each include an insulating material having a lower dielectric constant than that of a material included in the inter-layer insulating film 21, it is sufficient if the gate insulating film 22 is formed and this insulating material is then embedded in the through holes Ha and Hb. After the insulating material is embedded, a portion of this insulating material is removed with anisotropy. This forms the low-dielectric constant regions Ra.

After the gate insulating film 22 is formed, the embedded section 23B formed in the through holes Ha and Hb of the inter-layer insulating film 21 and the widened section 23W patterned in a predetermined shape is formed on the inter-layer insulating film 21 as illustrated in FIG. 16B. This forms the gate electrode 23. This gate electrode 23 is formed, for example, by subsequently performing mask evaporation on Ni (nickel) and Au (gold).

After the gate electrode 23 is formed, the through hole H22 is formed in the gate insulating film 22 between the through hole Hb and the through hole Hb2 as illustrated in FIG. 16C. The through hole H22 is formed, for example, by using dry etching. The second insulating layer 21b is exposed on the bottom surface of the through hole H22.

After the through hole H22 of the gate insulating film 22 is formed, wet etching is performed on the second insulating layer 21b via this through hole H22. This subjects the second insulating layer 21b around the through hole H22 to side etching and causes the low-dielectric constant region Rb to be formed in the second insulating layer 21b. The use of appropriate materials allows the selection ratio of the second insulating layer 21b to the gate insulating film 22 for wet etching to be increased. This makes it possible to suppress film reduction in the gate insulating film 22 or the like and suppress the degradation of the semiconductor layer 10 and gate electrode 23. At the time of this wet etching on the second insulating layer 21b, the first insulating layer 21a between the through hole Ha and the through hole Ha2 may be removed. The semiconductor device 1B illustrated in FIGS. 14 and 15 is completed through such steps.

The semiconductor device 1B according to the present modification example is also provided with the gate insulating film 22 between the gate electrode 23 (embedded section 23B) and the semiconductor layer 10 as with the above-described semiconductor device 1. For example, this makes it possible to suppress decrease in the off characteristic such as the occurrence of a leak current and decrease in a withstand voltage. This makes it possible to improve the transistor characteristic.

In addition, the low-dielectric constant regions Ra and Rb between the gate electrode 23 and the drain electrode 24d are wider than the low-dielectric constant region Ra between the gate electrode 23 and the source electrode 24s. This makes it possible to further decrease the gate-drain capacity (Cgd) without increasing the distance between the gate electrode 23 and the source electrode 24s. That is, it is possible to effectively decrease the gate-drain capacity (Cgd) while suppressing increase in the source resistance. The semiconductor device 1B is favorable in a case where it is requested to keep the low source resistance as the device characteristic.

In the semiconductor device 1B, the low-dielectric constant regions Ra of the first insulating layer 21a are widened in the width direction and the low-dielectric constant region Rb of the second insulating layer 21b in the stacking direction is provided. That is, adjusting the size of the low-dielectric constant region Rb of the second insulating layer 21b makes it possible to enlarge the low-dielectric constant regions Ra and Rb between the gate electrode 23 and the drain electrode 24d. This makes it possible to further improve the design freedom.

### Application Example

The semiconductor devices 1, 1A, and 1B described in the embodiment and modification examples 1 and 2 as described above are applicable to a variety of electronic apparatuses. For example, the semiconductor devices 1, 1A, and 1B are each used for a wireless communication apparatus in a mobile communication system and the like. In particular, the semiconductor devices 1, 1A, and 1B are each used as an RF switch, a power amplifier, or the like thereof. Such a wireless communication apparatus attains the effects especially when having the communication frequency of a UHF (ultra high frequency) band or higher.

In other words, the semiconductor devices 1, 1A, and 1B each used for an RF switch or a power amplifier of a wireless communication apparatus each allow the wireless communication apparatus to be speedier, more efficient, and less power consuming. The speedier, more efficient, and less power consuming device allows especially a mobile communication terminal to be used for a longer time. This allows mobility to be increased.

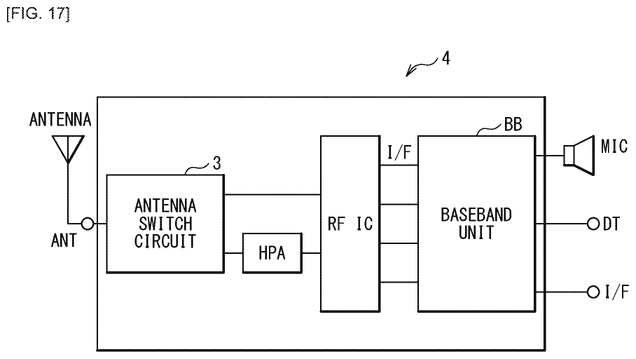

FIG. 17 illustrates an example of the configuration of a wireless communication apparatus (wireless communication apparatus 4). This wireless communication apparatus 4 is, for example, a mobile phone system that has multiple functions such as sound, data communication, and LAN coupling. The wireless communication apparatus 4 includes, for example, an antenna ANT, an antenna switch circuit 3, a high power amplifier HPA, a radio frequency integrated circuit RFIC (Radio Frequency Integrated Circuit), a baseband unit BB, a sound output unit MIC, a data output unit DT, an interface unit I/F (e.g., wireless LAN (W-LAN; Wireless Local Area Network), Bluetooth (registered trademark), or the like). The radio frequency integrated circuit RFIC and the baseband unit BB may be coupled through the interface unit I/F. For example, the antenna switch circuit 3 or the high power amplifier HPA includes any of the above-described semiconductor devices 1, 1A, and 1B.

In this wireless communication apparatus 4, during transmission, i.e., when a transmission signal is outputted to the antenna ANT from a transmission system of the wireless communication apparatus 4, a transmission signal outputted from the baseband unit BB is outputted to the antenna ANT via the radio frequency integrated circuit RFIC, the high power amplifier HPA, and the antenna switch circuit 3.

During reception, i.e., when a signal received by the antenna ANT is inputted to a reception system of the wireless communication apparatus, a reception signal may be inputted to the baseband unit BB via the antenna switch circuit 3 and the radio frequency integrated circuit RFIC. The signal processed by the baseband unit BB may be outputted from output units such as the sound output unit MIC, the data output unit DT, and the interface unit I/F.

The above has described the present technology with reference to the embodiment and the modification examples, but the present technology is not limited to the above-described embodiment and the like. It is possible to make various kinds of modifications thereof. For example, each of the components of the semiconductor devices 1, 1A, and 1B exemplified in the above-described embodiment and the like, the disposition thereof, the number thereof, and the like are mere examples. All of the components do not necessarily have to be included. In addition, another component may be further included.

In addition, the material and thickness of each layer, the method and conditions of forming each layer, or the like described in the above-described embodiment and the like are not limited. Each layer may include another material and have other thickness. Alternatively, each layer may be formed in another method under another condition. For example, in the above-described embodiment or the like, the case has been described where the semiconductor layer 10 includes a GaN-based compound semiconductor material. The semiconductor layer 10 may, however, include, for example, another compound semiconductor material such as a GaAs (gallium arsenide)-based material or the like. Alternatively, the semiconductor layer 10 may include a semiconductor material such as Si (silicon).

In addition, in the above-described modification examples 1 and 2 (FIGS. 12 to 15), the case has been described where the low-dielectric constant region Ra (or the low-dielectric constant regions Ra and Rb) between the gate electrode 23 and the drain electrode 24d is wider than the low-dielectric constant region Ra between the gate electrode 23 and the source electrode 24s. The low-dielectric constant region Ra (or the low-dielectric constant regions Ra and Rb) between the gate electrode 23 and the source electrode 24s may be, however, wider than the low-dielectric constant region Ra between the gate electrode 23 and the drain electrode 24d in accordance with the required device characteristic.

It is to be noted that the effects described in this specification are mere examples, but non-limiting. In addition, there may be other effects.

It is to be noted that the present technology may also be configured as follows.

(1)

A semiconductor device including:

a semiconductor layer;

an inter-layer insulating film having a through hole and a low-dielectric constant region, the through hole being provided to be opposed to the semiconductor layer, the low-dielectric constant region being provided to at least a portion of an area around the through hole;

a gate electrode including an embedded section and a widened section, the embedded section being embedded in the through hole of the inter-layer insulating film, the widened section being opposed to the semiconductor layer with the inter-layer insulating film interposed between the widened section and the semiconductor layer and being widened to an area around the embedded section; and

a gate insulating film provided between the embedded section of the gate electrode and the semiconductor layer.

(2)

The semiconductor device according to (1), in which the inter-layer insulating film includes a first insulating layer and a second insulating layer, the first insulating layer being provided with the low-dielectric constant region, the second insulating layer being provided between the first insulating layer and the widened section of the gate electrode.

(3)

The semiconductor device according to (2), in which the through hole includes a first through hole and a second through hole, the first through hole being provided to the first insulating layer, the second through hole being provided to the second insulating layer in communication with the first through hole and having a smaller width than a width of the first through hole.

(4)

The semiconductor device according to (2) or (3), in which the first insulating layer and the second insulating layer are each provided with the low-dielectric constant region.

(5)

The semiconductor device according to any one of (1) to (4), in which the low-dielectric constant region includes a space provided to the inter-layer insulating film.

(6)

The semiconductor device according to any one of (1) to (5), in which the low-dielectric constant region is provided to surround the embedded section of the gate electrode.

(7)

The semiconductor device according to any one of (1) to (6), further including a substrate, in which

the semiconductor layer, the gate insulating film, the inter-layer insulating film, and the gate electrode are provided on the substrate in this order.

(8)

The semiconductor device according to any one of (1) to (7), further including paired source and drain electrodes that are electrically coupled to the semiconductor layer.

(9)

The semiconductor device according to (8), in which the low-dielectric constant region is disposed between the gate electrode and each of the paired source and drain electrodes.

(10)

The semiconductor device according to (9), in which the low-dielectric constant region disposed between the gate electrode and one of the paired source and drain electrodes is different in size from the low-dielectric constant region disposed between the gate electrode and another of the paired source and drain electrodes.

(11)

The semiconductor device according to any one of (1) to (10), in which the gate insulating film is also provided between the low-dielectric constant region of the inter-layer insulating film and the semiconductor layer.

(12)

The semiconductor device according to any one of (1) to (11), in which

the semiconductor layer includes a channel layer and a barrier layer, the barrier layer being provided between the channel layer and the gate insulating film, and

the barrier layer includes a compound semiconductor having a wider band gap than a band gap of the channel layer.

(13)

The semiconductor device according to any one of (1) to (12), in which the semiconductor layer includes a compound semiconductor material.

(14)

An electronic apparatus including

a semiconductor device including
a semiconductor layer,
an inter-layer insulating film having a through hole and a low-dielectric constant region, the through hole being provided to be opposed to the semiconductor layer, the low-dielectric constant region being provided to at least a portion of an area around the through hole,
a gate electrode including an embedded section and a widened section, the embedded section being embedded in the through hole of the inter-layer insulating film, the widened section being opposed to the semiconductor layer with the inter-layer insulating film interposed between the widened section and the semiconductor layer and being widened to an area around the embedded section, and
a gate insulating film provided between the embedded section of the gate electrode and the semiconductor layer.
   (15)

A method of manufacturing a semiconductor device, the method including:

forming a semiconductor layer;

forming an inter-layer insulating film on the semiconductor layer;

forming a through hole and a low-dielectric constant region in the inter-layer insulating film, the through hole being disposed to be opposed to the semiconductor layer, the low-dielectric constant region being provided to at least a portion of an area around the through hole;

forming a gate insulating film on at least a bottom of the through hole; and

forming a gate electrode by embedding an electrically conductive film in the through hole of the inter-layer insulating film via the gate insulating film and covering the through hole with the electrically conductive film widened to an area of the through hole.

(16)

The method of manufacturing the semiconductor device according to (15), in which

the inter-layer insulating film is formed by forming a first insulating layer and a second insulating layer on the semiconductor layer in this order, and

the through hole and the low-dielectric constant region are formed by forming a second through hole in the second insulating layer and forming a first through hole and the low-dielectric constant region in the first insulating layer, the first through hole communicating with the second through hole.

(17)

The method of manufacturing the semiconductor device according to (16), in which

the second through hole is formed by using dry etching, and

the first through hole is formed by using wet etching.

This application claims the priority on the basis of Japanese Patent Application No. 2018-44046 filed on Mar. 12, 2018 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. A semiconductor device comprising:
a semiconductor layer;
an inter-layer insulating film having a through hole and a low-dielectric constant region, the through hole being provided to be opposed to the semiconductor layer, the low-dielectric constant region being provided to at least a portion of an area around the through hole;
a gate electrode including an embedded section and a widened section, the embedded section being embedded in the through hole of the inter-layer insulating film, the widened section being opposed to the semiconductor layer with the inter-layer insulating film interposed between the widened section and the semiconductor layer and being widened to an area around the embedded section; and
a gate insulating film provided between the embedded section of the gate electrode and the semiconductor layer.

2. The semiconductor device according to claim 1, wherein the inter-layer insulating film includes a first insulating layer and a second insulating layer, the first insulating layer being provided with the low-dielectric constant region, the second insulating layer being provided between the first insulating layer and the widened section of the gate electrode.

3. The semiconductor device according to claim 2, wherein the through hole includes a first through hole and a second through hole, the first through hole being provided to the first insulating layer, the second through hole being provided to the second insulating layer in communication with the first through hole and having a smaller width than a width of the first through hole.

4. The semiconductor device according to claim 2, wherein the first insulating layer and the second insulating layer are each provided with the low-dielectric constant region.

5. The semiconductor device according to claim 1, wherein the low-dielectric constant region includes a space provided to the inter-layer insulating film.

6. The semiconductor device according to claim 1, wherein the low-dielectric constant region is provided to surround the embedded section of the gate electrode.

7. The semiconductor device according to claim 1, further comprising a substrate, wherein
the semiconductor layer, the gate insulating film, the inter-layer insulating film, and the gate electrode are provided on the substrate in this order.

8. The semiconductor device according to claim 1, further comprising paired source and drain electrodes that are electrically coupled to the semiconductor layer.

9. The semiconductor device according to claim 8, wherein the low-dielectric constant region is disposed between the gate electrode and each of the paired source and drain electrodes.

10. The semiconductor device according to claim 9, wherein the low-dielectric constant region disposed between the gate electrode and one of the paired source and drain electrodes is different in size from the low-dielectric constant region disposed between the gate electrode and another of the paired source and drain electrodes.

11. The semiconductor device according to claim 1, wherein the gate insulating film is also provided between the low-dielectric constant region of the inter-layer insulating film and the semiconductor layer.

12. The semiconductor device according to claim 1, wherein
the semiconductor layer includes a channel layer and a barrier layer, the barrier layer being provided between the channel layer and the gate insulating film, and
the barrier layer includes a compound semiconductor having a wider band gap than a band gap of the channel layer.

13. The semiconductor device according to claim 1, wherein the semiconductor layer includes a compound semiconductor material.

14. An electronic apparatus comprising
a semiconductor device including
a semiconductor layer,
an inter-layer insulating film having a through hole and a low-dielectric constant region, the through hole being provided to be opposed to the semiconductor layer, the low-dielectric constant region being provided to at least a portion of an area around the through hole,
a gate electrode including an embedded section and a widened section, the embedded section being embedded in the through hole of the inter-layer insulating film, the widened section being opposed to the semiconductor layer with the inter-layer insulating film interposed between the widened section and the semiconductor layer and being widened to an area around the embedded section, and
a gate insulating film provided between the embedded section of the gate electrode and the semiconductor layer.

15. A method of manufacturing a semiconductor device, the method comprising:
forming a semiconductor layer;
forming an inter-layer insulating film on the semiconductor layer;
forming a through hole and a low-dielectric constant region in the inter-layer insulating film, the through hole being disposed to be opposed to the semiconductor layer, the low-dielectric constant region being provided to at least a portion of an area around the through hole;
forming a gate insulating film on at least a bottom of the through hole; and
forming a gate electrode by embedding an electrically conductive film in the through hole of the inter-layer insulating film via the gate insulating film and covering the through hole with the electrically conductive film widened to an area of the through hole.

16. The method of manufacturing the semiconductor device according to claim 15, wherein
the inter-layer insulating film is formed by forming a first insulating layer and a second insulating layer on the semiconductor layer in this order, and
the through hole and the low-dielectric constant region are formed by forming a second through hole in the second insulating layer and forming a first through hole and the low-dielectric constant region in the first insulating layer, the first through hole communicating with the second through hole.

17. The method of manufacturing the semiconductor device according to claim 16, wherein
the second through hole is formed by using dry etching, and
the first through hole is formed by using wet etching.
